(19) United States
(12) Patent Application Publication
(10) Pub. No.: US 2024/0313057 A1
(43) Pub. Date: Sep. 19, 2024

(54) SILICON CARBIDE SEMICONDUCTOR DEVICE AND METHOD FOR MANUFACTURING THE SAME

(71) Applicant: Hitachi, Ltd., Tokyo (JP)

(72) Inventors: Tomoka SUEMATSU, Tokyo (JP); Takeru Suto, Tokyo (JP)

(73) Assignee: Hitachi, Ltd., Tokyo (JP)

(21) Appl. No.: 18/575,060

(22) PCT Filed: Aug. 24, 2022
(86) PCT No.: PCT/JP2022/031942

§ 371 Date: Dec. 28, 2023

(30) Foreign Application Priority Data
Sep. 22, 2021 (JP) 2021-154358

(51) Int. Cl. H01L 29/16; H01L 29/06; H01L 29/66; H01L 29/78

(52) U.S. Cl. CPC H01L 29/1608; H01L 29/0607; H01L 29/0696; H01L 29/66734; H01L 29/7813

(57) ABSTRACT

A silicon carbide semiconductor device comprises: a trench formed in an upper surface of a semiconductor layer and having first and second lateral surfaces opposing each other in a first direction along an upper surface of the semiconductor layer; a gate electrode on the inside of the trench with an insulating film therebetween; a body layer adjoining the first lateral surface; a current spread region adjoining each of the first and second lateral surfaces; and a guard region covering corners of a bottom surface of the trench on the first lateral surface side and spaced apart from corners of the bottom surface of the trench on the second lateral surface side. In a first direction, the film thickness of the insulating film covering the second lateral surface is greater than the film thickness of the insulating film covering the first lateral surface.

### TECHNICAL FIELD

The present invention relates to a silicon carbide semiconductor device which is a power semiconductor device and particularly relates to a device having a trench structure and a method for manufacturing the same.

### BACKGROUND ART

Semiconductor power elements are required to have a low on-resistance and a low switching loss in addition to a high breakdown voltage, but silicon (Si) power elements, which are the current mainstream, are approaching the theoretical performance limit. Silicon carbide (SiC) has a dielectric breakdown field strength about ten times larger than that of Si. Therefore, the element resistance can be theoretically reduced by thirty times or more by thinning the drift layer that maintains the breakdown voltage to about 1/10 and increasing the impurity concentration about a hundred times. In addition, since the band gap is about three times larger than that of Si, high-temperature operation is also possible, and SiC semiconductor elements are expected to have performance exceeding that of Si semiconductor elements, and development of SiC power devices has been advanced.

PTL 1 (JP 2015-72999 A) describes a semiconductor device including an n type substrate made of silicon carbide, an n type drift layer on the substrate, and a plurality of trenches formed in a stripe shape on the drift layer. Here, it is described that a gate electrode formed in each trench via an insulating film and an n type current dispersion layer formed on a drift layer and having an impurity concentration higher than that of the drift layer are included. The gate electrode constitutes a metal oxide semiconductor field effect transistor (MOSFET), and the bottom of the trench is covered with a p type bottom layer.

### CITATION LIST

### Patent Literature

PTL 1: JP 2015-72999 A

PTL 2: JP 2021-12934 A

### SUMMARY OF INVENTION

### Technical Problem

In the structure having the trench, the area of the channel can be increased, and the on-resistance is expected to decrease. However, in general, there is a trade-off relationship between the on-resistance and the breakdown voltage. In addition, since a large electric field is applied to the insulating film in the trench, it is also important to relax the electric field of the insulating film. As a technique for alleviating the electric field in the insulating film, for example, as described in PTL 1 and PTL 2, it is effective to cover the bottom of the trench with a p type layer.

However, when the p type layer covering the entire bottom of the trench is formed, it is necessary to ensure a large interval between adjacent trenches, and thus the cell pitch increases. In addition, in PTL 1, a p type layer is further formed between trenches in order to prevent the gate insulating film from being broken by the surge due to the floating potential of the p type layer at the bottom of the trench. This p type layer increases the cell pitch, and further, since a depletion layer is formed from the p type layer, the on-resistance increases.

PTL 2 describes a structure in which a channel is in a vertical direction based on the structure of PTL 1, and a bottom of a trench is covered with a p type bottom layer. However, in the structure of PTL 2, when reducing the cell pitch aiming at low on-resistance, there is a problem that the trench interval affects the width of the JFET region and the JFET resistance increases.

Other objects and novel features will become apparent from the description of the specification and the accompanying drawings.

### Solution to Problem

The outline of typical aspects of the embodiments disclosed in the present application will be briefly described as follows.

A silicon carbide semiconductor device according to an embodiment includes: a trench formed on an upper surface of a semiconductor layer, the trench including a first side surface and a second side surface facing each other in a first direction along the upper surface of the semiconductor layer; a gate electrode formed inside the trench via an insulating film; a body layer in contact with the first side surface; a current diffusion region in contact with each of the first side surface and the second side surface; and a guard region covering a corner of a bottom surface of the trench on a side of the first side surface and separated from a corner of the bottom surface of the trench on a side of the second side surface. A film thickness of the insulating film covering the first side surface in the first direction is larger than a film thickness of the insulating film covering the second side surface. Here, the current diffusion region is separated from the side surface in the second direction intersecting the first direction in plan view, and the guard region covers all the corners of the four corners of the bottom surface of the trench.

A method for manufacturing a silicon carbide semiconductor device according to an embodiment includes: forming a source region, a body layer, a current diffusion region, and a drift layer in order from an upper surface side of a semiconductor substrate containing silicon carbide, and forming a guard region in the drift layer; and forming a trench and a gate electrode in the trench on the upper surface of the semiconductor substrate. The trench includes a first side surface and a second side surface facing each other in a first direction along the upper surface of the semiconductor substrate, the current diffusion region is separated from the side surface in the second direction intersecting the first direction in plan view, and the guard region covers all four corners of the bottom surface of the trench. Here, in the forming of the gate electrode, a portion facing the second side surface in the conductive film embedded in the trench via the insulating film is removed to form the gate electrode including the conductive film on the first side surface side.

### Advantageous Effects of Invention

The effects obtained by typical aspects of the invention disclosed in the present application will be briefly described as follows.

According to the present invention, the performance of the silicon carbide semiconductor device can be improved.

### BRIEF DESCRIPTION OF DRAWINGS

FIG. 1 is a perspective view illustrating a silicon carbide semiconductor device according to a first embodiment of the present invention.

FIG. 2 is a plan view illustrating the silicon carbide semiconductor device according to the first embodiment of the present invention.

FIG. 3 is a plan view illustrating the silicon carbide semiconductor device according to the first embodiment of the present invention.

FIG. 4 is a cross-sectional view taken along line A-A in FIG. 3.

FIG. 5 is a cross-sectional view taken along line B-B in FIG. 3.

FIG. 6 is an enlarged cross-sectional view illustrating a part of FIG. 4.

FIG. 7 is a cross-sectional view for explaining a method for manufacturing the silicon carbide semiconductor device according to the first embodiment of the present invention.

FIG. 8 is a cross-sectional view for explaining a method for manufacturing the silicon carbide semiconductor device subsequent to FIG. 7.

FIG. 9 is a cross-sectional view for explaining a method for manufacturing the silicon carbide semiconductor device subsequent to FIG. 8.

FIG. 10 is a cross-sectional view for explaining a method for manufacturing the silicon carbide semiconductor device subsequent to FIG. 9.

FIG. 11 is a cross-sectional view for explaining a method for manufacturing the silicon carbide semiconductor device subsequent to FIG. 10.

FIG. 12 is a cross-sectional view for explaining a method for manufacturing the silicon carbide semiconductor device subsequent to FIG. 11.

FIG. 13 is a cross-sectional view for explaining a method for manufacturing the silicon carbide semiconductor device subsequent to FIG. 12.

FIG. 14 is a cross-sectional view for explaining a method for manufacturing the silicon carbide semiconductor device subsequent to FIG. 13.

FIG. 15 is a perspective view illustrating a silicon carbide semiconductor device according to a second embodiment of the present invention.

FIG. 16 is a plan view illustrating the silicon carbide semiconductor device according to the second embodiment of the present invention.

FIG. 17 is a plan view illustrating the silicon carbide semiconductor device according to the second embodiment of the present invention.

FIG. 18 is a cross-sectional view taken along line C-C in FIG. 17.

FIG. 19 is a cross-sectional view taken along line D-D in FIG. 17.

FIG. 20 is a cross-sectional view for explaining a method for manufacturing the silicon carbide semiconductor device according to the second embodiment of the present invention.

FIG. 21 is a cross-sectional view for explaining a method for manufacturing the silicon carbide semiconductor device subsequent to FIG. 20.

FIG. 22 is a cross-sectional view for explaining a method for manufacturing the silicon carbide semiconductor device subsequent to FIG. 21.

FIG. 23 is a cross-sectional view for explaining a method for manufacturing the silicon carbide semiconductor device subsequent to FIG. 22.

FIG. 24 is a cross-sectional view for explaining a method for manufacturing the silicon carbide semiconductor device subsequent to FIG. 23.

FIG. 25 is a plan view illustrating a silicon carbide semiconductor device according to a third embodiment of the present invention.

FIG. 26 is a cross-sectional view illustrating the silicon carbide semiconductor device according to the third embodiment of the present invention.

FIG. 27 is a cross-sectional view illustrating a silicon carbide semiconductor device according to a comparative example.

### DESCRIPTION OF EMBODIMENTS

Hereinafter, embodiments of the present invention will be described on the basis of the drawings. Further, members having the same functions in the drawings for describing the embodiments will be attached with the same symbol, and the redundant description will be omitted. In the following embodiments, the description of the same or similar parts will not be repeated in principle unless otherwise necessary. In addition, in the drawings describing the embodiments, hatching may be applied even in a plan view, a perspective view, or the like for easy understanding of the configuration. Furthermore, in the drawings describing the embodiments, hatching may be omitted in the cross-sectional view for easy understanding of the configuration.

In addition, “−” and “+” are signs indicating relative impurity concentrations of conductivity types of n type or p type, and for example, the concentration of n type impurities increases in the order of “n⁻⁻”, “n⁻”, “n”, “n⁺”, and “n⁺⁺”. In the following embodiments, the n type corresponds to a first conductivity type, and the p type corresponds to a second conductivity type, but may be reversed.

### Details of Room for Improvement

Hereinafter, details of room for improvement will be described with reference to FIG. 27. As illustrated in FIG. 27, in the comparative example, an n⁻ type drift layer 4, an n type current diffusion region 17, a p type body layer 5, and a source region 6 are formed in this order on a silicon carbide (SiC) substrate on which an n⁺ type drain region 12 made of SiC (silicon carbide) is formed. A plurality of trenches 9 are formed side by side on the upper surface of the semiconductor substrate including the drain region 12, the drift layer 4, the current diffusion region 17, the body layer 5, and the n⁺⁺ type source region 6. A bottom of each trench 9 reaches an intermediate depth of the current diffusion region 17, and a guard region 8a is formed in the semiconductor substrate so as to cover the bottom. A gate electrode 2 is formed in the trench 9 via an insulating film 7f which is a gate insulating film, and an upper surface of the gate electrode 2 is covered with an insulating film 16. A source electrode 1 covering the gate electrode 2 and the insulating film 16 is formed on the semiconductor substrate. The guard regions 8a at the bottoms of the adjacent trenches 9 are separated from each other, and a JFET region 13 is formed in a region between the trenches 9. A drain electrode 3 is formed in contact with the lower surface of the drain region 12, that is, the lower surface of the semiconductor substrate. The gate electrode 2, the source region 6, and the drain region 12 constitute a SiC power MISFET (Metal Insulator Semiconductor Field Effect Transistor).

In the structure having a trench as in the comparative example, the area of the channel is increased, and the on-resistance is expected to decrease. However, in general, there is a trade-off relationship between the on-resistance and the breakdown voltage. In particular, in the case of having a JFET region, when the width of the JFET region is narrowed, the breakdown voltage increases, and the resistance (JFET resistance) also increases. Therefore, the design of the JFET region is very important. Furthermore, SiC has a wider band gap than Si and has a high dielectric breakdown strength, but an electric field applied to the insulating film increases accordingly, and thus it is important to relax the electric field of the insulating film. When the electric field in the insulating film is strong, a leakage current occurs in the gate insulating film, which leads to a decrease in the lifetime of the gate insulating film and device malfunction such as dielectric breakdown of the gate insulating film.

In the above-described comparative example, the bottom of the trench 9 is covered with the p type guard region 8a, thereby alleviating the electric field applied to the insulating film 7f. However, from the viewpoint of preventing an increase in on-resistance, it is necessary to have a predetermined distance between the adjacent guard regions 8a. Therefore, when the guard region 8a covering the entire bottom of the trench 9 is formed, it is necessary to ensure a large interval between the adjacent trenches 9. That is, when the adjacent guard regions 8a are brought close to each other, the width of the JFET region is narrowed and the resistance (JFET resistance) is increased. Therefore, in order to prevent such an increase in resistance, it is necessary to ensure a large cell pitch.

In the comparative example, the potential of the p type layer at the bottom of the trench 9 is floating, so that the gate insulating film may be broken by the surge. In order to prevent this, it is conceivable to further form a p type layer between the trench 9 and the trench 9. However, since the p type layer increases the cell pitch and a depletion layer is formed from the p type layer, the on-resistance increases.

As described above, in the SiC power MISFET including the trench, there is room for improvement in achieving both the reduction of the on-resistance and the securing of the breakdown voltage.

In addition, the trench 9 having a rectangular planar shape and extending in a predetermined direction in plan view has a side surface that is a long side and a side surface that is a short side. When a side surface which is a short side of the trench 9 is used as a channel in plan view, characteristics of the SiC power MISFET vary. As described above, there is room for improvement that the locations where the channels of the trenches 9 are formed should be unified to the side surfaces that are the long sides of the trenches 9.

In addition, in the SiC power MISFET including the trench gate electrode, the electric field is particularly likely to concentrate at the corner of the bottom surface of the trench 9, that is, the side surface on the short side, the side surface on the long side, and the three-dimensional corner which is the boundary of the bottom surface of the trench 9. Therefore, there is room for improvement in alleviating the electric field at the corner of the trench 9 in order to prevent defects such as dielectric breakdown.

Therefore, in the embodiment of the present application, contrivance is made to solve the above-described room for improvement. Hereinafter, a technical idea in the embodiment to which this contrivance is applied will be described.

### First Embodiment

Hereinafter, a silicon carbide semiconductor device will be described with reference to the drawings by exemplifying a trench type MOSFET which is a SiC power MISFET having a side surface in a trench (groove, recess) as a channel region.

### Structure of Silicon Carbide Semiconductor Device

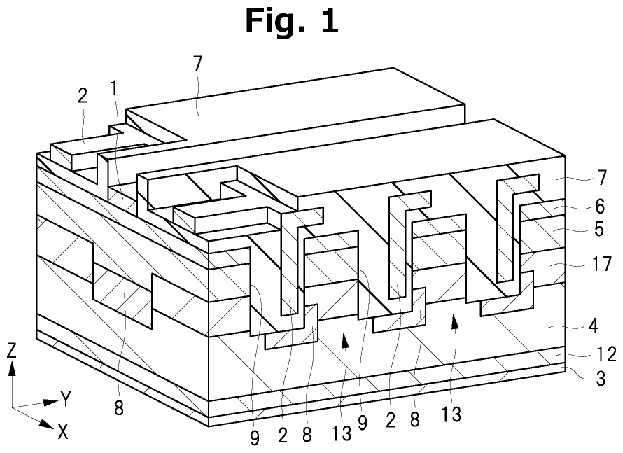

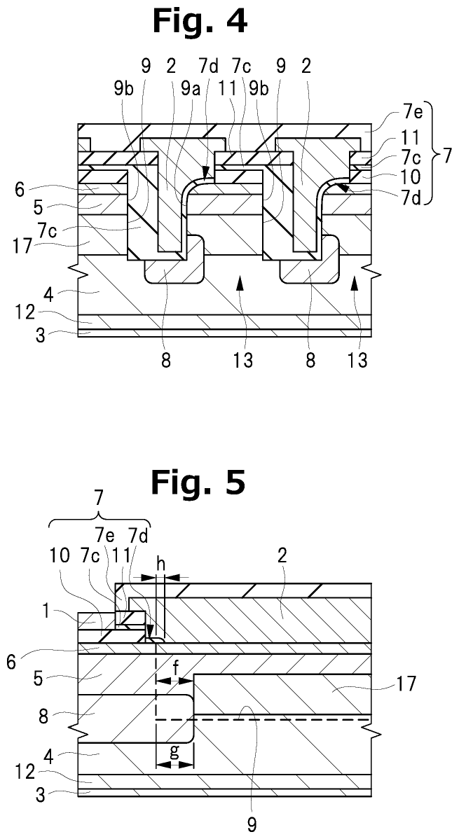

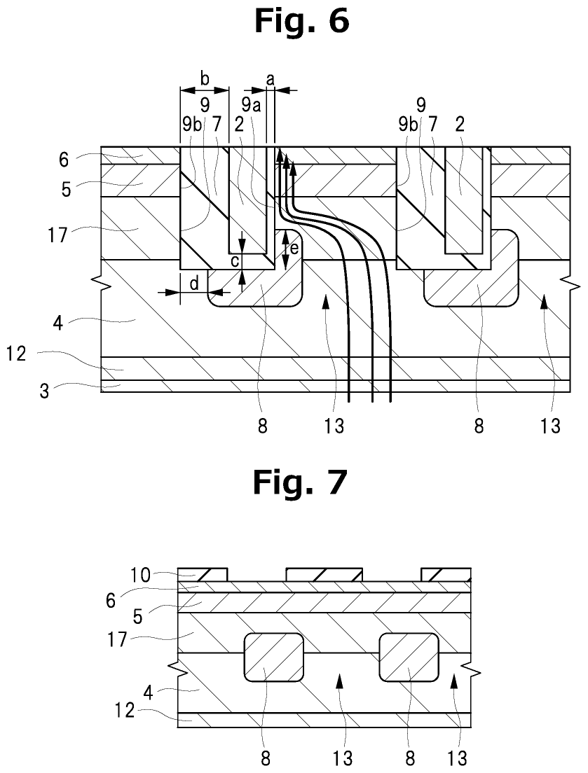

A structure of a silicon carbide semiconductor device according to a first embodiment will be described with reference to FIGS. 1 to 6. In FIG. 1, illustration of an insulating film 7 (a gate insulating film and an interlayer insulating film) is partially omitted for easy understanding of the drawing. In addition, FIGS. 1 and 6 simply illustrate a part of the structure of the SiC power MISFET, and FIG. 4 illustrates a more specific structure of the SiC power MISFET. Therefore, the structure of the gate electrode 2 and the like is partially different between FIG. 4 and FIGS. 1 and 6. FIG. 4 is a cross-sectional view taken along line A-A in FIG. 3, and FIG. 5 is a cross-sectional view taken along line B-B in FIG. 3.

As illustrated in FIGS. 1 and 4, the silicon carbide semiconductor device according to the present embodiment includes an n type silicon carbide (SiC) epitaxial substrate (hereinafter, referred to as a SiC epitaxial substrate or a semiconductor substrate). The SiC epitaxial substrate (semiconductor substrate) is a laminated substrate including an n⁺ type silicon carbide substrate containing silicon carbide and an n⁻⁻ type epitaxial layer (semiconductor layer) formed on the silicon carbide substrate by an epitaxial growth method. The epitaxial layer is a semiconductor layer containing SiC. In each drawing of the present application, the drift layer 4 which is an n⁻⁻ type semiconductor region mainly constituting an epitaxial layer is illustrated, and the drain region 12 constituted by a silicon carbide substrate of an n⁺ type semiconductor region is illustrated below the drift layer 4. That is, in FIGS. 1 and 4 and other cross-sectional views, a portion indicated as the drain region 12 is a silicon carbide substrate.

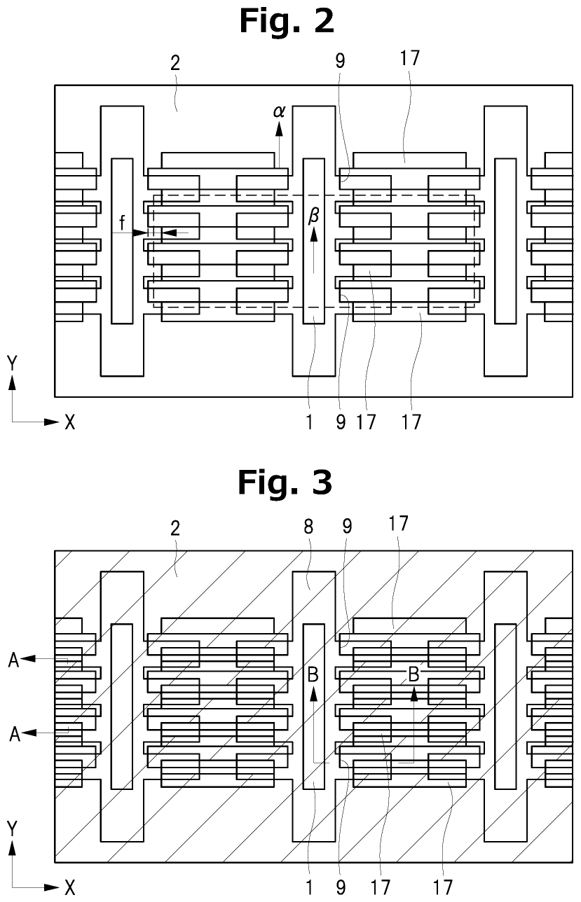

FIG. 2 shows only the source electrode 1 extending in the Y direction, the plurality of trenches 9 extending in the X direction and arranged in the Y direction, the current diffusion region 17 formed in contact with the side surface of each trench in the Y direction, and the gate electrode 2. In addition, in FIG. 3, a hatched guard region 8 is illustrated in addition to those configurations of FIG. 2. The guard region 8 and the current diffusion region 17 are formed at an intermediate depth of the semiconductor substrate, and in FIGS. 2 and 3, the guard region 8 and the current diffusion region 17 are illustrated to be transmitted through the gate electrode 2, the source electrode 1, and the like. The perspective view illustrated in FIG. 1 illustrates a structure of a region indicated by a broken line in FIG. 2.

As illustrated in FIG. 2, the cell array constituting the silicon carbide semiconductor device of the present embodiment has a configuration in which a plurality of unit cells having a predetermined planar layout are arranged in X. However, the unit cells may be arranged in a matrix in the X direction and the Y direction instead of being arranged only in the X direction. One unit cell is formed, for example, in a half region on one source electrode 1 side in a region between centers of two adjacent source electrodes 1 in the X direction. That is, a plurality of unit cells are arranged while being line-symmetrically inverted in the X direction in plan view.

The X direction and the Y direction illustrated in FIG. 2 are directions along the upper surface (main surface) of the semiconductor substrate. That is, the X direction and the Y direction are directions along the upper surface of the semiconductor layer, and are directions along the upper surface of the silicon carbide substrate. The X direction and the Y direction are orthogonal to each other in plan view. The Y direction corresponds to a first direction, and the X direction corresponds to a second direction.

One unit cell includes the source region 6 (see FIG. 2) that is an n⁺⁺ type semiconductor region formed on the upper surface of the semiconductor substrate, and the trench 9 formed on the upper surface of the semiconductor substrate in contact with the source region 6 in plan view. In FIG. 2, the source region 6 formed on the upper surface of the semiconductor substrate is not illustrated. The source region 6 is formed in a region other than the region where the trench 9 is formed in plan view.

The trenches 9 are formed in a matrix in the Y direction and the X direction. Specifically, in one unit cell, the plurality of trenches 9 are arranged side by side in the Y direction in a region adjacent to the source electrode 1 in the X direction. The shape of the trench 9 in plan view is, for example, rectangular, and the upper ends of all the side surfaces (four sides) of the trench 9 in plan view are in contact with the source region 6. FIGS. 2 and 3 do not illustrate the shapes of the gate insulating film and the gate electrode 2 formed in the trench 9. In the present application, the gate electrode 2 in the trench 9 may be referred to as a trench gate electrode.

Here, the trench 9 extends in the X direction, so that the channel width of the SiC power MISFET can be easily increased. Such an increase in the channel width is difficult to realize in the trench type MOSFET in which the trench gate electrode extends in the Y direction similarly to the source electrode 1. On the other hand, in the present embodiment, since the trench gate electrodes are arranged to be separated from each other in the Y direction, the trench 9 can be extended in the X direction, and the channel width can be easily increased. As a result, the on-resistance of the SiC power MISFET can be reduced.

Here, a plurality of trenches 9 are arranged in parallel in the trench formation region. This can increase the channel width and reduce the loss. The trench formation region as used herein is a region where a plurality of trenches 9 are formed side by side in the Y direction.

As illustrated in FIG. 2, the current diffusion region 17 is in contact with the side surface of the trench 9 between the trenches 9 adjacent in the Y direction, and extends along the longitudinal direction (long side direction, X direction) of the trench 9. That is, the current diffusion region 17 is in contact with each of the two side surfaces that are the long sides of the trench 9 in plan view. On the other hand, the current diffusion region 17 is not in contact with the side surface which is the short side of the trench 9 in plan view. In other words, the current diffusion region 17 is separated from the side surface which is the short side. That is, the current diffusion region 17 is separated from the end of the trench 9 in the X direction. Here, the current diffusion region 17 is not in contact with both ends in the X direction of the side surface which is the long side of the trench 9.

As illustrated in FIG. 3, in plan view, the trench 9 and the gate electrode 2 overlap near one of the long sides parallel to each other of the trenches 9. In this manner, a trench gate electrode is formed in a region near the long side where the trench 9 and the gate electrode 2 overlap. The guard region 8 overlaps the region, that is, a region where the trench 9 near one of the long sides parallel to each other of the trenches 9 and the gate electrode 2 overlap in plan view. That is, the guard region 8 is formed so as to overlap with the trench gate electrode in plan view. In addition, the guard region 8 is not formed on the other of the long sides parallel to each other of the trenches 9 and the vicinity thereof in plan view. In other words, the guard region 8 is separated from at least a part of the other long side among the long sides parallel to each other of the trenches 9 in plan view. This is because a current flows at a high density near a side surface 9b (see FIG. 6) of the trench 9 as described later with reference to FIG. 6.

In addition, a region where the source electrode 1 is formed (source contact region) and a trench formation region are arranged in parallel to each other. The JFET region 13 (see FIG. 4) to be described later is disposed in a direction (X direction) orthogonal to the extending direction (Y direction) of the source electrode 1. As a result, since the source contact region, the trench formation region, and the JFET region 13 can be independently designed, design flexibility can be improved. In particular, since the JFET region 13 is independent of the source electrode 1 and can be designed independently of the source electrode 1, the pitch of the JFET region 13 can be narrowed and the number of the JFET regions 13 can be increased.

Here, FIG. 2 illustrates a direction a along a normal line at an interface between a side surface which is a long side of the trench 9 and the current diffusion region 17 and a direction β in which the source contact region extends. The range of the angle Y formed by the direction α and the direction β is preferably, for example, −30°<γ<30°. That is, since SiC is a hexagonal crystal, the plane orientation changes at 60°, and the characteristics greatly change. Therefore, in the case of |γ|=30°, since the components of the two plane orientations are mixed in the channel, the amount of change in the normal vector is preferably within 30° in order to align the plane orientations of the main channels. It is conceivable that the planar shape of the trench 9 is not actually rectangular, but has a shape close to an ellipse with rounded corners. Even in such a case, when the range of the angle γ falls within −30°<γ<30°, a change in the characteristics of the SiC power MISFET can be prevented.

As illustrated in FIGS. 4 and 5, the drain region 12 is formed in the semiconductor substrate, and the drift layer 4 is formed in contact with the drain region 12 on the drain region 12 in the semiconductor substrate. The n type impurity concentration of the drain region 12 is higher than the n type impurity concentration of the drift layer 4. The drift layer 4, the current diffusion region 17, the body layer 5, the source region 6, the guard region 8, the drain region 12, and the JFET region 13 are formed in the epitaxial layer. The source region 6 corresponds to a first semiconductor region, the body layer 5 corresponds to a second semiconductor region, the drift layer 4 corresponds to a third semiconductor region, and the drain region 12 corresponds to a fourth semiconductor region. The guard region 8 corresponds to a fifth semiconductor region, the current diffusion region 17 corresponds to a sixth semiconductor region, and the JFET region 13 corresponds to a seventh semiconductor region.

A drain electrode 3 is formed in contact with the lower surface of the drain region 12, that is, the lower surface of the semiconductor substrate. That is, the lower surface of the semiconductor substrate is covered with the drain electrode 3, and the drain electrode 3 is electrically connected to the drain region 12. The drain electrode 3 is made of, for example, a laminated conductor film containing gold (Au). On the upper surface of the semiconductor substrate (the upper surface of the epitaxial layer), the source region 6 is formed over a predetermined depth from the upper surface of the semiconductor substrate. Between the source region 6 and the drift layer 4, the body layer 5, which is a p type semiconductor region, is formed in contact with the lower surface of the source region 6. The current diffusion region 17, which is an n type semiconductor region, is formed between the body layer 5 and the drift layer 4 in contact with the lower surface of the body layer 5. The source region 6 has a higher n type impurity concentration than the current diffusion region 17, and is electrically connected to the source electrode 1. The lower surface of the body layer 5 is in contact with the drift layer 4. The current diffusion region 17 has an n type impurity concentration higher than that of the drift region 4 and lower than that of the source region 6.

The trenches 9 are formed from the upper surface of the semiconductor substrate to an intermediate depth in the drift layer 4, extend in the X direction, and are arranged side by side in the Y direction. The current diffusion region 17, the body layer 5, and the source region 6 are in contact with both side surfaces of the trench 9 in the Y direction in order from the bottom.

The gate electrode 2 is embedded in the trench 9 via the insulating film 7. However, the film thickness of the insulating film 7 in the trench 9 is not the same on one side surface side and the other side surface side of the trench 9 in the lateral direction (Y direction) of the trench 9 in plan view. As illustrated in FIG. 4, the trench 9 has side surfaces 9a and 9b facing each other in the Y direction. The side surface 9a corresponds to a first side surface, and the side surface 9b corresponds to a second side surface. It is conceivable that the side surface of the trench 9 has a taper, and in this case, the width of the trench 9 in the X direction and the Y direction is larger on the upper side than on the lower side. Therefore, a line perpendicular to the side surface 9a does not intersect perpendicularly to the side surface 9b, but even in such a case, the side surfaces 9a and 9b will be described as facing each other in the present application.

Here, a plurality of trenches 9 are arranged in the Y direction without reversing the planar layout thereof. Therefore, among the adjacent trenches 9, the side surface 9a of one trench 9 is adjacent to the side surface 9b of the other trench 9. That is, among the adjacent trenches 9, none of the other trenches 9, the insulating film 7, and the gate electrode 2 are interposed between the side surface 9a of one trench 9 and the side surface 9b of the other trench 9. Therefore, the side surface 9a and the side surface 9b are alternately arranged in the Y direction.

The insulating film 7 includes insulating films 7c, 7d, 7e, 10, and 11. A boundary portion between the upper end on the side surface 9a side of the trench 9 and the upper surface of the semiconductor substrate is gently connected, and is rounded as compared with a boundary portion between the upper end of the side surface 9b and the upper surface of the semiconductor substrate. The insulating film 10 is adjacent to the side surface 9b in plan view, but is separated from the side surface 9a. The side surface 9a and the upper surface of the semiconductor substrate between the side surface 9a and the insulating film 10 are continuously covered with the insulating film 7d which is a gate insulating film. The insulating film 11 is formed on the insulating film 10 via the insulating film 7c. The side surface 9a of the trench 9 is covered with the insulating film 7d having a relatively thin film thickness, whereas the side surface 9b is covered with the insulating film 7c having a film thickness larger than that of the insulating film 7d.

In the trench 9, the gate electrode 2 is embedded between the insulating films 7c and 7d. A part of the gate electrode 2 is also embedded immediately above the trench 9 and immediately above the semiconductor substrate between the side surface 9a and the insulating film 10, and the other part of the gate electrode 2 is formed so as to cover the upper surface of the insulating film 11. The gate electrode 2 is covered with the insulating film 7e which is an interlayer film.

In the trench 9, the thick insulating film 7c is formed between the gate electrode 2 and the side surface 9b, whereas the thin insulating film 7d is only formed between the gate electrode 2 and the side surface 9a, and the insulating film 7c is not formed. Therefore, as illustrated in FIG. 6, the film thickness b in the Y direction of the insulating film 7 covering the side surface 9b is larger than the film thickness a in the Y direction of the insulating film 7 covering the side surface 9a, and the gate electrode 2 is formed closer to the side surface 9a side in the trench 9.

As illustrated in FIGS. 1 and 5, the source electrode 1 is disposed on the semiconductor substrate without the insulating film 7 interposed therebetween, and extends in the Y direction between the adjacent insulating films 7. The source electrode 1 is connected to the source region 6. That is, the source electrode 1 is electrically connected to the source region 6. The source electrode 1 may be electrically connected to the source region 6 via a silicide layer (not illustrated).

As illustrated in FIGS. 1, 4, and 5, the guard region 8, the current diffusion region 17, and the JFET region 13 extend in the X direction and are arranged in plurals in the Y direction. That is, the guard region 8, the current diffusion region 17, and the JFET region 13 are arranged in a stripe shape in plan view. Therefore, a plurality of trenches 9 in which the side surface 9a is in contact with the body layer 5 and a plurality of body layers 5 in contact with the trenches 9 are formed side by side in the Y direction.

Here, as illustrated in FIGS. 1 and 3 to 5, in the drift layer 4, the guard region 8 which is a p type semiconductor region is formed to be separated from each of the body layer 5 and the drain region 12. The p type impurity concentration of the guard region 8 is higher than the p type impurity concentration of the body layer 5. One guard region 8 is formed in contact with each of the plurality of trenches 9. The guard region 8 in contact with one trench 9 extends in the X direction. The guard region 8 is in contact with the bottom surface and the side surface 9a of the trench 9, and is not in contact with the side surface 9b. In addition, the guard region 8 is separated from the bottom surface of the trench 9 near the side surface 9b. That is, the guard region 8 is formed so as to cover the corner on the side surface 9a side of the trench 9, and the corner on the side surface 9b side is exposed. In other words, the guard region 8 is in contact with the first surface extending from the side surface 9a of the trench 9 to a part of the bottom surface of the trench 9, and is separated from the second surface extending from the side surface 9b of the trench 9 to the other part of the bottom surface of the trench 9.

The corner of the trench 9 here refers to the vicinity of the boundary including the boundary between the bottom surface and the side surface of the trench 9. Even when the bottom surface and the side surface of the trench 9 are smoothly connected by a curved surface, this curved portion is referred to as a corner in the present application. The guard region 8 covering the corner of one trench 9 is separated from the other trenches 9. The bottom surface of the trench 9 is located above the bottom surface of the guard region 8 and below the uppermost surface of the guard region 8. In the X direction, the side surface 9a of the trench 9 is located between the side surfaces on both sides of the guard region 8.

In the drift layer 4, a junction field effect transistor (JFET) region 13 which is an n type or n⁻⁻ type semiconductor region is formed side by side with the guard region 8 in the Y direction. Specifically, under the body layer 5, the JFET region 13 is adjacent to the guard region 8. The JFET region 13 extends in the X direction along with the guard region 8 immediately below the source electrode 1. The JFET region 13 is a region located between the guard regions 8 adjacent to each other in the Y direction.

The n type impurity concentration of the JFET region 13 is equal to or higher than the n type impurity concentration of the drift layer 4. The n type impurity concentration of the JFET region 13 is lower than the n type impurity concentration of the source region 6. The JFET region 13 is a region in which a depletion layer extends from each of the opposing side surfaces of the adjacent guard regions 8 when the SiC power MISFET is in the OFF state, and the current path is closed when the depletion layers are in contact with each other.

FIG. 5 illustrates a cross section along the X direction and including the source electrode 1, the current diffusion region 17, and the guard region 8. However, among the structures illustrated in FIG. 5, the structure above the semiconductor substrate, that is, the structure above the source region 6 is a structure on the back side in the Y direction with respect to the cross section of the semiconductor substrate, and is a structure in a cross section including the trench 9 indicated by a broken line in FIG. 5. That is, in FIG. 5, the outline of the trench 9, which is located deeper than the current diffusion region 17 and is not originally illustrated, is indicated by a broken line, and the gate electrode 2 located immediately above the trench is illustrated. Although not illustrated in FIG. 5, a thin insulating film 7 is formed between the semiconductor layer including the source region 6 and the gate electrode 2, and the gate electrode 2 and the source region 6 are insulated from each other.

As illustrated in FIG. 5, a part of the current diffusion region 17 is formed above the upper end of the guard region 8, and a part of the guard region 8 is formed below the lower end of the current diffusion region 17. The guard region 8 and the current diffusion region 17 overlap the trench 9 in the Y direction. Although not illustrated, on the right side of FIG. 5, a line-symmetric structure around the right end of FIG. 5 is formed. Therefore, in the region adjacent to the side surface 9a which is the long side of the trench 9, the p type semiconductor region (the body layer 5 or the guard region 8), the current diffusion region 17, and the p type semiconductor region (the body layer 5 or the guard region 8) are arranged in this order in the X direction. In other words, in the region in contact with the trench 9 in the Y direction, the body layer 5 (or the guard region 8), the current diffusion region 17, and the body layer 5 (or the guard region 8) are arranged in this order in the X direction. That is, in the X direction, the distance f between the side surface which is the short side of the trench 9 and the current diffusion region 17, that is, the width of the body layer 5 is represented by 0<f (see FIGS. 2 and 5). This means that the trench 9 is formed across the p type semiconductor region, the current diffusion region 17, and the p type semiconductor region.

In this manner, the current diffusion region 17 in contact with the side surface (the side surface in the lateral direction of the trench 9), which is the long side of the trench 9, is terminated so as not to reach the end of the trench 9 in the X direction, whereby the end of the trench 9 in the X direction, particularly the side surface, which is the short side, is separated from the current diffusion region 17. As a result, only the side surface which is the long side of the trench 9 is used as the channel of the SiC power MISFET, and the current can be suppressed from flowing through the side surface which is the short side.

In the X direction, a distance g between a side surface which is a short side of the trench 9 and the guard region 8 is represented by 0<g (see FIGS. 3 and 5). The height of the lower surface of the trench 9 is higher than the lower surface of the guard region 8 and lower than the upper surface of the guard region 8. Here, the relationship between the distance g and the distance h that is the thickness of the insulating film 7 (7d) covering the side surface that is the short side of the trench 9 is represented by g≥h. In other words, the distance h is a distance between the side surface of the trench 9 and the gate electrode 2 in the X direction. That is, in the X direction, the shortest distance g from the side surface of the trench 9 to the terminal end of the guard region 8 in contact with the trench 9 is equal to or longer than the distance h between the side surface and the gate electrode 2, which means that the corner of the lower end of the gate electrode 2 in the trench 9 is covered with the guard region 8.

As illustrated in FIG. 6, the film thickness c of the insulating film 7 (7a) immediately below the gate electrode 2, which is the shortest distance between the bottom surface of the trench 9 and the gate electrode 2, is larger than the film thickness a in the Y direction of the insulating film 7 covering the side surface 9a. As a result, the electric field applied from the bottom of the trench 9 to the insulating film 7 can be alleviated. The film thickness c is a thickness of the insulating film covering the bottom surface of the trench 9 in the insulating film 7 in a direction perpendicular to the upper surface of the semiconductor substrate. The film thickness c is, for example, 50 to 500 nm.

In the Y direction, a distance d, which is the shortest distance from the side surface 9b of the trench 9 to the guard region 8 in contact with the trench 9, is larger than the film thickness b. Therefore, the electric field of the insulating film 7 near the corner on the side surface 9b side of the trench 9 can be alleviated. The distance d is a distance from the boundary between the side surface 9b of the trench 9 and the bottom surface of the trench 9 to the boundary between the bottom surface of the trench 9 and the guard region 8. The distance d is, for example, 100 to 500 nm.

In addition, in the thickness direction of the semiconductor substrate (direction perpendicular to the upper surface of the semiconductor substrate), a distance e from the upper surface (uppermost surface) of the guard region 8 to the bottom surface of the trench 9 is larger than the film thickness c. However, it is sufficient that the guard region 8 covers the corner on the side surface 9a side of the trench 9. That is, the distance e may be equal to or less than the film thickness c. The fact that e>0 means that the guard region 8 covers the corner on the side surface 9a side of the trench 9. This makes it possible to reduce lines of electric force from the bottom of the trench 9. When the distance e is larger than the film thickness c, the corner of the gate electrode 2 on the side surface 9a side is covered with the guard region 8, so that the effect of alleviating the concentration of the electric field to the corner of the gate electrode 2 can be further expected. The distance e is, for example, 100 to 1000 nm.

### Operation of Silicon Carbide Semiconductor Device

Next, the operation of the SiC power MISFET according to the present embodiment will be described with reference to FIG. 6. The SiC power MISFET includes at least a drain region 12, a source region 6, a body layer 5, and a gate electrode 2. When the SiC power MISFET is in the ON state, as illustrated in FIG. 6, a channel is formed in the body layer 5 adjacent to the side surface 9a of the trench 9. On the other hand, it is difficult to form a channel in the body layer 5 adjacent to the side surface 9b of the trench 9. This is because the insulating film 7 covering the side surface 9b of the trench 9 is larger than the insulating film 7 covering the side surface 9a. In addition, since the insulating film 7 covering the side surface 9b of the trench 9 is larger than the insulating film 7 covering the side surface 9a, an accumulation layer in which carriers (electrons in this case) are accumulated is formed in the drift layer 4 adjacent to the side surface 9b.

As a result, when the SiC power MISFET is in the ON state, the current flowing from the drain region 12 side easily flows into the accumulation layer near the side surface 9b of one trench 9 in the drift layer 4 between the trenches 9 adjacent to each other. In the ON state, the current flows in the channel formed in the body layer 5 adjacent to the side surface 9a of the other trench 9. Therefore, as indicated by thick lines in FIG. 6, the current flows in the accumulation layer near the side surface 9b of the trench 9 in the drift layer 4, and flows in the channel formed near the side surface 9a of the other trench 9 in the body layer 5. The density of the current flowing through the channel in the body layer 5 between the adjacent trenches 9 is higher than the density of the current flowing in the drift layer 4 between the adjacent trenches 9. Therefore, it can be said that the main current path of the SiC power MISFET exists not on the side surface 9b side but on the side surface 9a side of the trench 9.

When the SiC power MISFET is in the OFF state, no channel is formed, and thus no current flows. However, the guard region 8 and the JFET region 13 are provided below the trench 9 in order to suppress a minute current between the source and the drain at the time of OFF and improve the breakdown voltage. That is, by providing the guard region 8, when the SiC power MISFET is in the OFF state, the depletion layer extending from the adjacent guard region 8 closes in the JFET region 13 between the guard regions 8, so that the current path between the source and the drain is cut off. That is, the guard region 8 has a role of connecting a depletion layer generated around the guard region 8 between the adjacent guard regions 8, thereby realizing suppression of a minute current and improvement of a breakdown voltage. Therefore, even if the impurity concentration of the drift layer 4 is increased for the purpose of reducing the resistance of the element, the breakdown voltage at the time of OFF can be secured. In addition, the guard region 8 has a role of preventing an electric field from concentrating near the corner of the trench 9 and causing dielectric breakdown between the epitaxial layer and the gate electrode 2.

### Method for Manufacturing Silicon Carbide Semiconductor Device

Next, a method for manufacturing the silicon carbide semiconductor device according to the present embodiment will be described with reference to FIGS. 7 to 14. The polarities described below may be inverted between p type and n type.

First, as illustrated in FIG. 7, a silicon carbide substrate (wafer), that is, a SiC bulk substrate is prepared. The plane orientation of the upper surface of the silicon carbide substrate is a Si plane, a C plane, or another plane orientation, and the off angle of the upper surface is 4 degrees. The silicon carbide substrate may be a substrate produced using a sublimation method, a substrate using a solution method, a substrate using a gas growth method, or a substrate already provided with an epitaxial layer. Chemical mechanical polishing (CMP) may be performed before the epitaxial growth process described later. The n type impurity concentration of the silicon carbide substrate is, for example, 1×10¹⁸ cm^{-3 to} 1×10²¹ cm⁻³, and here, for example, 1×10¹⁸ cm⁻³. The silicon carbide substrate crystal type may be 4H-SiC, 6H, or 3C. Here, it is preferable to use a wafer having an OFF angle on the upper surface, but a just substrate may be used.

Next, an epitaxial layer is formed on the silicon carbide substrate by an epitaxial growth process. That is, epitaxial growth is performed by heating SiH₄ and C₃H₈ at a temperature of 1500° C. or higher using H₂ as a carrier gas. As a result, an epitaxial layer is formed on the silicon carbide substrate. The impurity concentration and film thickness of the epitaxial layer at this time vary depending on the device to be produced. The impurity concentration is, for example, about 1×10¹⁴ cm⁻³ to 1×10¹⁸ cm⁻³, and the film thickness is, for example, several μm to several tens of μm. A high-concentration buffer layer may be formed in the silicon carbide substrate before the epitaxial layer is formed. An impurity concentration of the buffer layer is about 1×10¹⁸ cm⁻³. This epitaxial layer is also called a drift layer 4.

Next, a step of forming the ion implantation region will be described. The p type implanted ion is Al (aluminum) or B (boron). The n type implanted ion is N (nitrogen) or P (phosphorus).

A p type body layer, an n type current diffusion region 17, a p type guard region 8, a JFET region 13, and an n⁺⁺ type source region 6 are formed by ion implantation over a predetermined depth in the drift layer 4 from the upper surface of the drift layer 4. The body layer 5 may be formed by an epitaxial growth method. The source region 6 is in contact with an upper surface of a wafer (upper surface of a semiconductor substrate) which is a SiC epitaxial substrate.

The body layer 5 is in contact with the source region 6 and is formed deeper than the source region 6. The current diffusion region 17 is in contact with the body layer 5 and is formed deeper than the body layer 5. A plurality of guard regions 8 are formed side by side in the drift layer 4 deeper than the body layer 5. The current diffusion region 17 and the JFET region 13 are regions connecting the body layer 5 and the drift layer 4. The JFET region 13 is a region sandwiched between the guard regions 8 adjacent to each other. The region between the adjacent guard regions 8 may be regarded as the JFET region 13 without performing the ion implantation for forming the JFET region 13, but the JFET region 13 may be formed by performing the ion implantation for reducing the resistance. Although the minimum configuration in which the SiC power MISFET operates has been described in the present embodiment, for example, a structure to which a function such as a termination region is added may be manufactured.

Subsequently, a carbon film as a cap material for impurity activation annealing is deposited around the semiconductor substrate including the silicon carbide substrate and the epitaxial layer. Thereafter, impurity activation annealing is performed at, for example, a temperature of 1600 to 1800° C. Thereafter, the carbon layer of the cap material is removed by oxygen plasma ashing. This annealing has an effect of preventing roughness of the surface of the semiconductor substrate. Thereafter, in order to obtain a cleaner surface, a thermal oxide film covering the surface of the semiconductor substrate may be formed, and then the thermal oxide film may be removed using a diluted hydrofluoric acid solution.

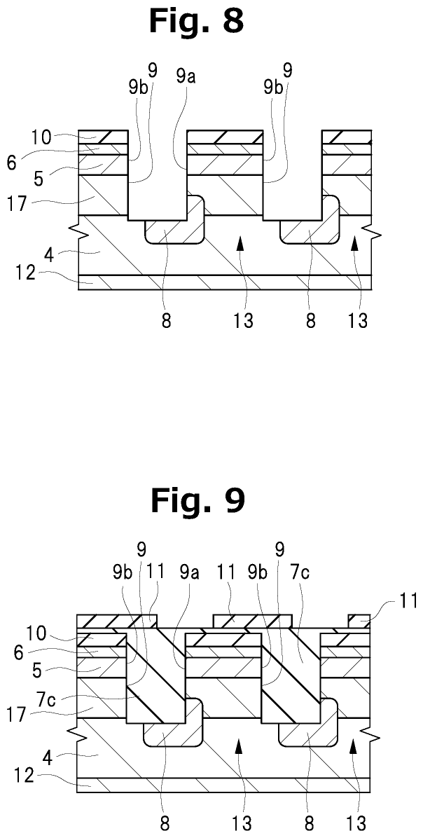

Next, as illustrated in FIG. 8, the trenches 9 are formed. Here, a trench 9 that penetrates the source region 6 and the body layer 5 and has a bottom accommodated in the drift layer is formed on the upper surface of the semiconductor substrate by etching using the insulating film 10 as a hard mask. The trench 9 has one side surface 9a and the other side surface 9b in the Y direction. The bottom surface of the trench 9 on the side surface 9a side reaches the intermediate depth of one guard region 8. On the other hand, the bottom surface of the trench 9 on the side surface 9b side is separated from the guard region 8. Thereafter, a treatment for cleaning the etched surface may be performed. In the processing, for example, a thermal oxide film covering the surface of the semiconductor substrate including the surface of the trench 9 is formed, and then the thermal oxide film is removed using a diluted hydrofluoric acid solution.

Next, as illustrated in FIG. 9, the inside of the trench 9 is filled using, for example, a chemical vapor deposition (CVD) method to form the insulating film 7c covering the side surface and the upper surface of the insulating film 10. The insulating film 7c is made of, for example, a silicon oxide film. Here, a deposited oxide film in which the trench 9 is completely filled is formed. The film thickness of the insulating film 7c is, for example, 100 to 1000 nm.

Subsequently, an insulating film 11 is formed on the insulating film 7c by using, for example, a CVD method. The insulating film 11 covers the insulating film 7c on the side surface 9b side in the trench 9 and exposes the insulating film 7c on the side surface 9a side in the trench 9 in plan view.

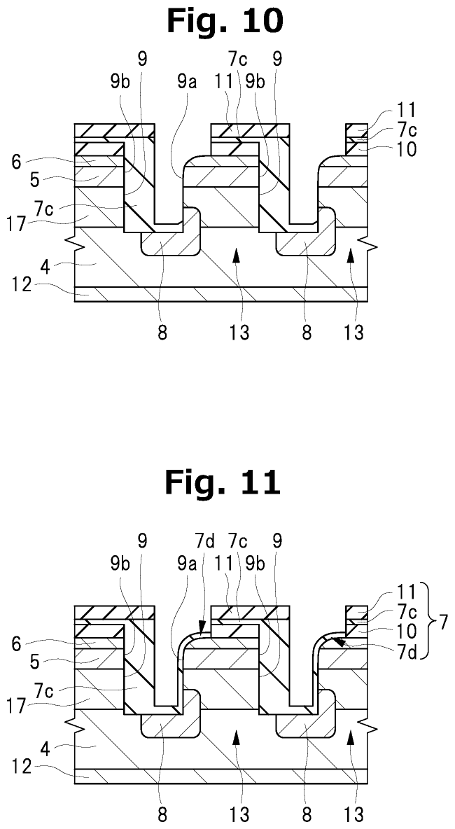

Next, as illustrated in FIG. 10, anisotropic etching (for example, dry etching) is performed using the insulating film 11 as a mask. As a result, the insulating film 7c is partially removed, and the side surface 9a and the upper surface of the semiconductor substrate adjacent to the side surface 9a and exposed from the insulating films 10 and 11 are exposed. At this time, by controlling the etching amount, the insulating film 7c covering the bottom surface of the trench 9 is left. As a result, the film thickness of the gate insulating film at the bottom of the trench 9 can be increased, and electric field alleviation at the bottom of the trench 9 can be realized. Note that the bottom surface of the trench 9 may be exposed by this etching process.

Next, as illustrated in FIG. 11, an insulating film 7d is formed by using, for example, a CVD method. Here, since the insulating film 7d is formed by a deposition method, it is actually conceivable that the insulating film 7d covers the insulating films 10 and 11 and the like, but in FIG. 11, the insulating film 7d is illustrated only near the side surface 9a of the trench 9. The insulating film 7d continuously covers the side surface 9a of the trench 9 and the upper surface of the semiconductor substrate adjacent to the side surface 9a and exposed from the insulating films 10 and 11. The film thickness of the insulating film 7d is, for example, 10 to 100 nm. The insulating films 7c, 7d, 10, and 11 constitute the insulating film 7. The insulating film 7 covering the bottom surface of the trench 9 includes one or both of the insulating films 7c and 7d.

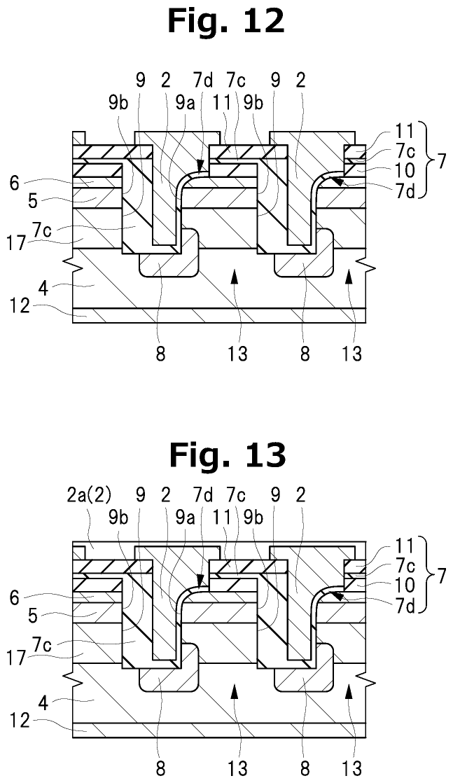

Next, as illustrated in FIG. 12, a first gate electrode forming step is performed. That is, the gate electrode 2 that fills the inside of the trench 9 is formed. Here, a conductive film, which is an n type polycrystalline silicon film, is formed on a semiconductor substrate with a thickness of, for example, 100 to 300 nm by, for example, a CVD method. Thereafter, the conductive film is patterned using a photolithography technique and an etching method, whereby the gate electrode 2 including the conductive film can be formed. Formed in the first gate electrode forming step is the gate electrode 2 in the portion extending in the X direction in the trench formation region (see FIG. 2).

Next, as illustrated in FIG. 13, a second gate electrode forming step is performed. That is, a conductive film 2a, which is an n type polycrystalline silicon film, is formed on the semiconductor substrate by, for example, a CVD method. Thereafter, the conductive film 2a is patterned using a photolithography technique and an etching method, whereby the gate electrode 2 including the conductive film 2a can be formed. That is, the conductive film 2a formed in the second gate electrode forming step constitutes the gate electrode 2 integrally with the conductive film formed in the first gate electrode forming step. The gate electrode 2 extending in the Y direction in the trench formation region and extending across the plurality of trenches is formed in the second gate electrode forming step (see FIG. 2). FIG. 13 illustrates the conductive film 2a located on the back side of the cross section illustrated in FIGS. 7 to 12.

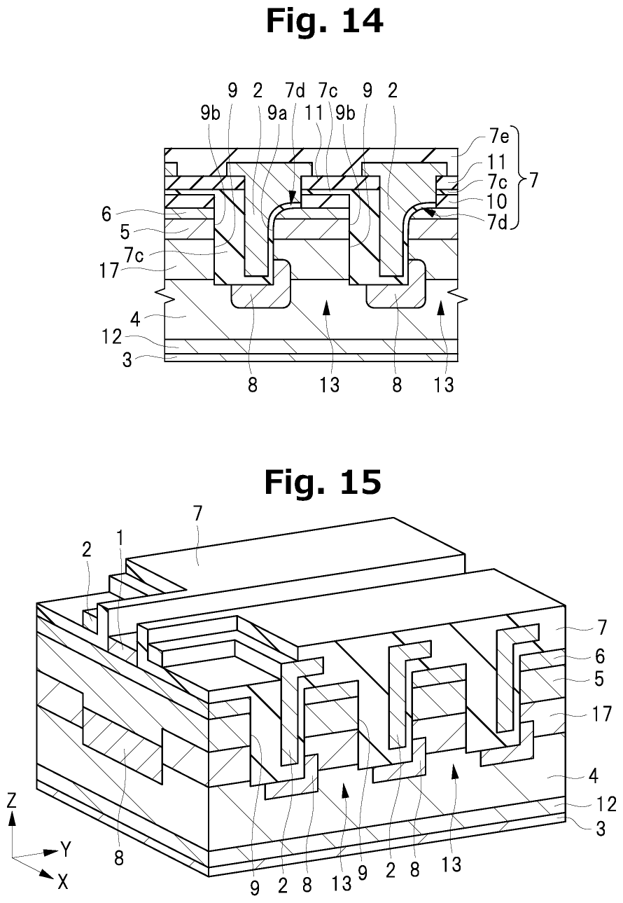

Next, as illustrated in FIG. 14, an insulating film 7e covering the gate electrode 2 and the insulating film 7 is formed on a semiconductor substrate by using, for example, a CVD method.

Subsequently, a connection hole for making contact with the source region 6 is opened in the insulating film 7. That is, the insulating film 7 is etched using the resist pattern formed on the insulating film 7 as a mask to form a connection hole (opening) that exposes the upper surface of the semiconductor substrate. Next, a metal film for silicide is deposited on the semiconductor substrate, and silicidation is performed by, for example, annealing treatment at 700° C. to 1000° C., thereby forming a silicide layer (not illustrated) in contact with the upper surface of the semiconductor substrate over the upper surface of the source region 6 at the bottom surface of the connection hole. Thereafter, although not illustrated, a connection hole for making contact with the gate electrode 2 is opened in the insulating film 7. That is, by etching the insulating film 7 using the resist pattern formed on the insulating film 7 as a mask, a connection hole (opening) that exposes the upper surface of the gate electrode 2 is formed.

Subsequently, the source electrode 1 is formed in the connection hole on the source region 6 of the insulating film 7. Thereafter, the lower surface of the drain region 12 on the lower surface side of the semiconductor substrate is also silicided to form a drain contact, and subsequently, the drain electrode 3 is formed. A material such as nickel (Ni) or aluminum (Al) is used for the metal film for silicide, the source electrode 1, and the drain electrode 3. Thereafter, the entire surface of the semiconductor substrate is covered with a surface protective film made of an insulator for device protection. Thereafter, the silicon carbide semiconductor device of the present embodiment is completed through a step of performing wiring to each electrode.

### Effects of Silicon Carbide Semiconductor Device

In the present embodiment, for the purpose of reducing the on-resistance and alleviating the electric field in the gate insulating film, a gate insulating film having a left-right asymmetric structure in a cross section is formed. Here, as illustrated in FIG. 6, the film thickness b of the insulating film 7 is larger than the film thickness a, and the p type guard region 8 is formed under the insulating film 7 at the trench corner below the channel formation surface serving as the main conduction path of the trench-type SiC power MISFET.

In the ON state of the SiC power MISFET, an accumulation layer is formed in an n type region (here, the drift layer 4) in contact with the side surface 9b, and a current passes through the accumulation layer near the side surface 9b, enters an inversion layer formed in the body layer 5 in contact with the side surface 9a, and flows from the source region 6 to the source electrode 1. Accordingly, the on-resistance can be reduced.

In addition, in the OFF state, the trench corner in contact with the side surface 9a is protected by the guard region 8, the electric field concentration does not occur, and the electric field is alleviated since the thick insulating film 7 exists at the trench corner in contact with the side surface 9b. Therefore, reliability is improved.

In addition, here, the guard region 8 at the bottom of the trench 9 is formed in a small region on one side (side surface 9a side) of the trench 9, and the guard region 8 is not formed on the other side (side surface 9b side) of the trench 9. Therefore, as compared with the comparative example in which the entire bottom surface of the trench 9 is covered with the guard region 8a (see FIG. 27), the interval between the adjacent trenches 9 can be narrowed. Therefore, the cell pitch can be reduced, and the on-resistance can be reduced. Therefore, both the reduction of the on-resistance and the securing of the breakdown voltage can be achieved.

In addition, here, a plurality of guard regions 8 are arranged in a stripe shape, and it is easy to supply a potential to each of the guard regions 8. Therefore, since the potential of the guard region 8 does not float, it is not necessary to further form a p type layer between the trenches 9 for the purpose of preventing breakdown of the gate insulating film due to the surge. Therefore, an increase in the cell pitch can be prevented.

In addition, on a side surface (a side surface which is a long side) in the lateral direction of the trench 9, the body layer 5 (or the guard region 8) which is a p type semiconductor region, the current diffusion region 17, and the body layer 5 (or the guard region 8) which is a p type semiconductor region are formed in this order in the X direction. In this manner, the current diffusion region 17 in contact with the side surface which is the long side of the trench 9 is terminated so as not to reach the end of the trench 9 in the X direction, whereby the current diffusion region 17 is separated from the end of the trench 9 in the X direction. As a result, only the side surface which is the long side of the trench 9 is used as the channel of the SiC power MISFET, and the current can be suppressed from flowing through the side surface which is the short side. Therefore, in the SiC power MISFET of the present embodiment, the side surface that is the short side of the trench is not used as the channel, and only the side surface that is the long side can be mainly used as the channel.

This makes it possible to unify the formation positions of the channels in each of the plurality of trenches 9 formed in the semiconductor substrate to the plane orientation along the long side, thereby preventing variations in the characteristics of the SiC power MISFET.

In addition, the relationship between the distance g illustrated in FIG. 5 and the distance h that is the thickness of the insulating film 7 covering the side surface that is the short side of the trench 9 is represented by g≥h. That is, all corners of the lower end of the gate electrode 2 in the trench 9 are covered with the guard region 8. In addition, all corners of the four corners of the bottom surface of the trench 9 are covered with the guard region 8. The corner of the trench 9 referred to herein is a three-dimensional corner which is a boundary between the side surface on the short side, the side surface on the long side, and the bottom surface of the trench 9. As a result, the corner of the trench gate electrode can be protected by the guard region 8 having a high concentration, so that the electric field concentration at the corner can be alleviated.

As described above, in the present embodiment, the above-described room for improvement can be solved, and the performance of the silicon carbide semiconductor device can be improved.

### Second Embodiment

The present embodiment is different from the first embodiment in a pattern of a gate electrode connecting trench gate electrodes arranged in the Y direction and a method for manufacturing a silicon carbide semiconductor device.

### Structure of Silicon Carbide Semiconductor Device

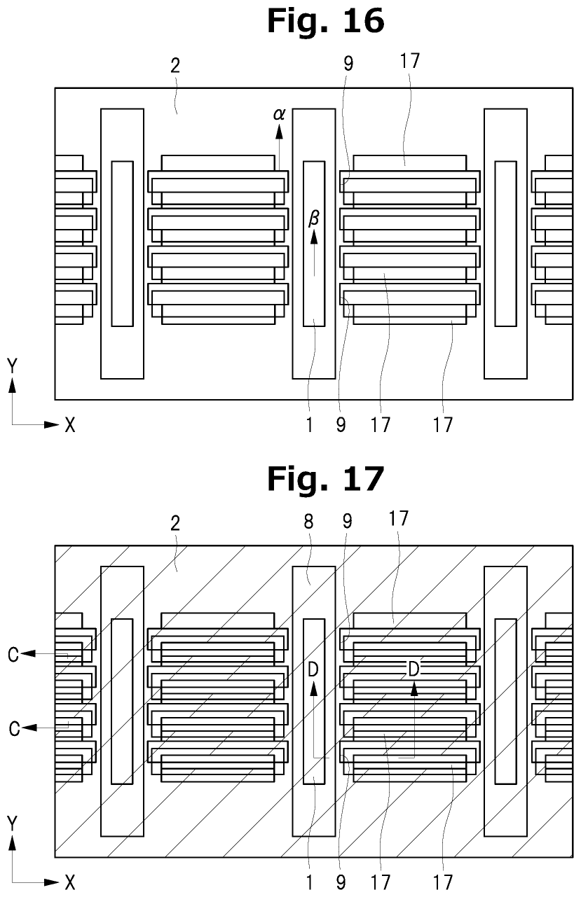

FIG. 15 is a perspective view of a SiC power MISFET according to the present embodiment. FIGS. 16 and 17 are plan views of the silicon carbide semiconductor device according to the present embodiment. Similarly to FIGS. 2 and 3, the guard region 8 is not illustrated in FIG. 16, and the guard region 8 is hatched in FIG. 17. Here, as illustrated in FIG. 1, the gate electrode 2 extending in the Y direction does not extend so as to straddle the central portion of the trench 9 in the X direction, but extends in the Y direction immediately above each of both ends of the trench 9 in the X direction. That is, the plurality of gate electrodes formed in a stripe shape side by side in the Y direction in the trench formation region are formed near the source electrode 1 and connected in parallel by the gate electrode 2 extending in the Y direction. All the regions where the gate electrode 2 extending in the Y direction and the trench 9 overlap in plan view overlap with the guard region 8. That is, the gate electrode 2 extending in the Y direction is separated from a region where the trench 9 and the guard region 8 do not overlap in plan view.

Here, FIG. 16 illustrates a direction α along a normal line at an interface between a side surface which is a long side of the trench 9 and the current diffusion region 17 and a direction β in which the source contact region extends. As described in the first embodiment, when the range of the angle γ formed by the direction α and the direction β is within −30°<γ<30°, a change in characteristics of the SiC power MISFET can be prevented.

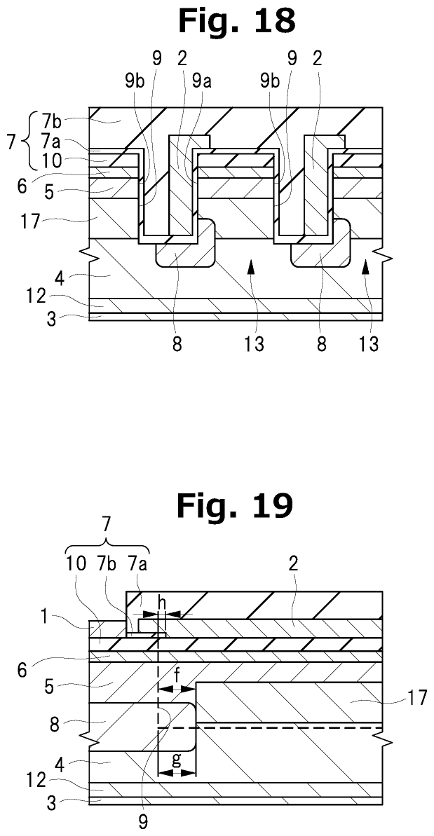

FIG. 18 is a cross-sectional view taken along line C-C in FIG. 17, and FIG. 19 is a cross-sectional view taken along line D-D in FIG. 17. As illustrated in FIG. 18, the structure in the semiconductor substrate is substantially the same as that of the first embodiment, but the structure of the insulating film and the gate electrode on the semiconductor substrate is different from that of the first embodiment.

Here, the insulating film 7 includes insulating films 7a, 7b, and 10. The insulating film 7a is a thin film continuously covering the entire side surface and the bottom surface of the trench 9 and the upper surface of the semiconductor substrate. The gate electrode 2 is formed from the inside of the trench 9 to the semiconductor substrate on the side surface 9a side (on the source region 6). On the semiconductor substrate (on the source region 6), the gate electrode 2 is formed via a laminated film including the insulating films 10 and 7a sequentially formed on the semiconductor substrate. The insulating film 7a covering the side surface 9b and the gate electrode 2 in the trench 9 are separated from each other, and a part of the insulating film 7b is embedded therebetween. The insulating film 7b outside the trench 9, that is, on the semiconductor substrate is an interlayer insulating film covering the insulating films 7a and 10 and the gate electrode 2. That is, the gate electrode 2 and the insulating films 7a and 7b are both formed from the inside of the trench 9 to the semiconductor substrate.

In the trench 9, the insulating films 7a and 7b are formed between the gate electrode 2 and the side surface 9b, whereas the insulating film 7a is only formed between the gate electrode 2 and the side surface 9a, and the insulating film 7b is not formed. Therefore, as illustrated in FIG. 6, the film thickness b in the Y direction of the insulating film 7 covering the side surface 9b is larger than the film thickness a in the Y direction of the insulating film 7 covering the side surface 9a, and the gate electrode 2 is formed closer to the side surface 9a side in the trench 9.

As illustrated in FIG. 19, here, similarly to the first embodiment, in the region in contact with the trench 9 in the Y direction, the body layer 5 (or the guard region 8) which is a p type semiconductor region, the current diffusion region 17, and the body layer 5 (or the guard region 8) which is a p type semiconductor region are sequentially formed in the X direction. That is, in the X direction, the distance f between the side surface which is the short side of the trench 9 and the current diffusion region 17, that is, the width of the body layer 5 is represented by 0<f (see FIGS. 16 and 19). As a result, a channel is prevented from being formed on the short side of the trench 9, and the plane orientation of the channel is aligned with the side surface which is the long side of the trench 9.

In the X direction, a distance g between a side surface which is a short side of the trench 9 and the guard region 8 is represented by 0<g (see FIGS. 17 and 19). The height of the lower surface of the trench 9 is higher than the lower surface of the guard region 8 and lower than the upper surface of the guard region 8. Here, the relationship between the distance g and the distance h that is the thickness of the insulating film 7 (7b) covering the side surface that is the short side of the trench 9 is represented by g≥h. This means that the corner of the lower end of the gate electrode 2 in the trench 9 is covered with the guard region 8. As a result, the electric field at the corner of the trench 9 can be alleviated.

### Method for Manufacturing Silicon Carbide Semiconductor Device

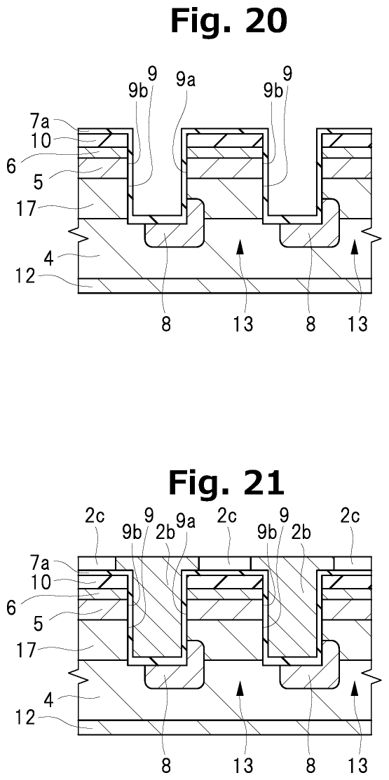

Next, a method for manufacturing the silicon carbide semiconductor device according to the present embodiment will be described with reference to FIGS. 20 to 24.

First, steps similar to the steps described with reference to FIGS. 7 and 8 are performed.

Next, as illustrated in FIG. 20, an insulating film 7a constituting a gate insulating film is formed on the semiconductor substrate. The thickness of the insulating film 7a is, for example, about 10 to 100 nm. The insulating film 7a is made of, for example, a deposited oxide insulating film. The film thickness of the insulating film 7a formed by the deposition method is larger in a portion covering the bottom surface of the trench 9 than in a portion covering each of the side surfaces 9a and 9b.

Next, as illustrated in FIG. 21, conductive films 2b and 2c, which are n type polycrystalline silicon films having a thickness of about 100 to 300 nm, formed on a semiconductor substrate. Here, the conductive film 2b is deposited by, for example, a CVD method. As a result, the conductive film 2b is embedded in the trench 9 via the insulating film 7a. Subsequently, the conductive film 2b is patterned using a photolithography technique and a dry etching method, thereby exposing a part of the upper surface of the insulating film 7a outside the trench 9. FIG. 21 illustrates, in addition to the cross section of the conductive film 2b, a conductive film 2c that is a pattern including the same film as the conductive film 2c and located deeper than the cross section illustrated in FIG. 20. The conductive film 2c is a pattern extending in the lateral direction of the trench 9 immediately above the end in the longitudinal direction of the trench 9. As described above, the second embodiment is different from the first embodiment in that a conductive film (gate electrode) extending in the lateral direction (Y direction) of the trench 9 can be formed by one process (film forming process and processing process) (see FIGS. 12 and 13).

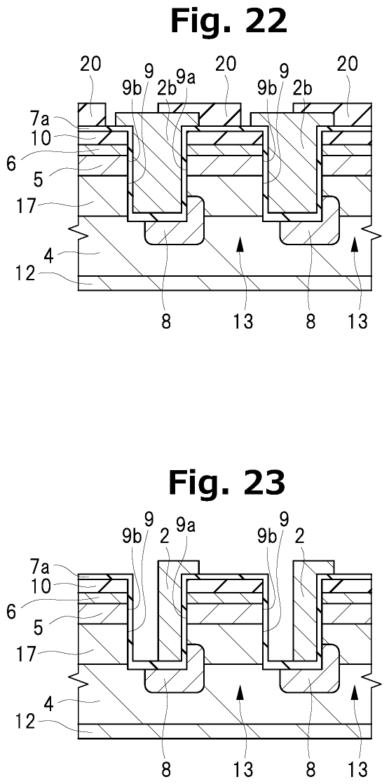

Next, as illustrated in FIG. 22, a resist pattern 20 including a photoresist film is formed on the semiconductor substrate. The resist pattern 20 exposes the conductive film 2b on the side surface 9b side in the trench 9 and covers the conductive film 2b and the conductive film 2c (see FIG. 21) on the side surface 9a side in the trench 9 in plan view.

Next, as illustrated in FIG. 23, dry etching (anisotropic etching) is performed using the resist pattern 20 as a mask, and then the resist pattern 20 is removed. Here, a portion of the conductive film 2b facing the side surface 9b is removed. In this way, the conductive film 2b on the side surface 9b side in the trench 9 is removed, and the gate electrode 2 including the conductive film 2b on the side surface 9a side in the trench 9 is formed. The conductive film 2c (not illustrated) also constitutes the gate electrode 2.

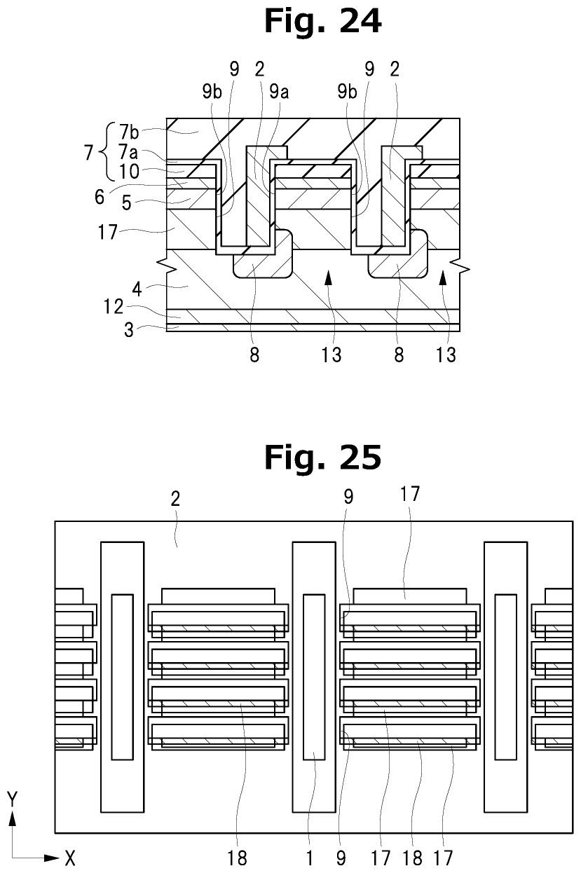

Next, as illustrated in FIG. 24, an insulating film 7b as an interlayer film is formed so as to cover the gate electrode 2. The insulating film 7b is made of, for example, a silicon oxide film, and is formed by, for example, a CVD method. As a result, the insulating film 7b is embedded in the region where the conductive film 2b is removed in the trench 9 by the etching step described with reference to FIG. 23. The insulating films 10, 7a, and 7b constitute the insulating film 7.

Thereafter, the source electrode 1 and the drain electrode 3 are formed in the same manner as in the step described with reference to FIG. 14. Thus, the silicon carbide semiconductor device of the present embodiment is completed.

### Effects of Silicon Carbide Semiconductor Device

Even in a case where a left-right asymmetric gate electrode is formed in a trench and then the trench is filled with an insulating film as in the present embodiment, the same effects as those of the first embodiment can be obtained.

That is, in the present embodiment, for the purpose of reducing the on-resistance and alleviating the electric field in the gate insulating film, a gate insulating film having a left-right asymmetric structure in a cross section is formed. Here, as illustrated in FIG. 6, the film thickness b of the insulating film 7 is larger than the film thickness a, and the p type guard region 8 is formed under the insulating film 7 at the trench corner below the channel formation surface serving as the main conduction path of the trench-type SiC power MISFET.

In the ON state of the SiC power MISFET, an accumulation layer is formed in an n type region (here, the drift layer 4) in contact with the side surface 9b, and a current passes through the accumulation layer near the side surface 9b, enters an inversion layer formed in the body layer 5 in contact with the side surface 9a, and flows from the source region 6 to the source electrode 1. Accordingly, the on-resistance can be reduced.

In addition, in the OFF state, the trench corner in contact with the side surface 9a is protected by the guard region 8, the electric field concentration does not occur, and the electric field is alleviated since the thick insulating film 7 exists at the trench corner in contact with the side surface 9b. Therefore, reliability is improved.

In addition, here, the guard region 8 at the bottom of the trench 9 is formed in a small region on one side (side surface 9a side) of the trench 9, and the guard region 8 is not formed on the other side (side surface 9b side) of the trench 9. Therefore, as compared with the comparative example in which the entire bottom surface of the trench 9 is covered with the guard region 8a (see FIG. 27), the interval between the adjacent trenches 9 can be narrowed. Therefore, the cell pitch can be reduced, and the on-resistance can be reduced. Therefore, both the reduction of the on-resistance and the securing of the breakdown voltage can be achieved.

In addition, here, a plurality of guard regions 8 are arranged in a stripe shape, and it is easy to supply a potential to each of the guard regions 8. Therefore, since the potential of the guard region 8 does not float, it is not necessary to further form a p type layer between the trenches 9 for the purpose of preventing breakdown of the gate insulating film due to the surge. Therefore, an increase in the cell pitch is prevented.

In addition, the current diffusion region 17 in contact with the side surface which is the long side of the trench 9 is terminated so as not to reach the end of the trench 9 in the X direction, whereby the current diffusion region 17 is separated from the end of the trench 9 in the X direction. As a result, only the side surface which is the long side of the trench 9 is used as the channel of the SiC power MISFET, and the current can be suppressed from flowing through the side surface which is the short side. Therefore, in the SiC power MISFET of the present embodiment, the side surface that is the short side of the trench is not used as the channel, and only the side surface that is the long side can be mainly used as the channel.

This makes it possible to unify the formation positions of the channels in each of the plurality of trenches 9 formed in the semiconductor substrate to the plane orientation along the long side, thereby preventing variations in the characteristics of the SiC power MISFET.

In addition, the relationship between the distance g illustrated in FIG. 19 and the thickness h of the insulating film 7 covering the side surface that is the short side of the trench 9 is represented by g≥h. That is, all corners of the lower end of the gate electrode 2 in the trench 9 are covered with the guard region 8. As a result, the corner of the trench gate electrode can be protected by the guard region 8 having a high concentration, so that the electric field concentration at the corner can be alleviated.

As described above, in the present embodiment, the performance of the silicon carbide semiconductor device can be improved.

In the present embodiment, as described with reference to FIG. 21, the conductive film (gate electrode) extending in the lateral direction (Y direction) of the trench 9 can be formed by one process (film forming process and processing process). That is, in the method for manufacturing the semiconductor device according to the present embodiment, as illustrated in FIG. 2, when it is attempted to form a pattern of the gate electrode 2 extending in the Y direction immediately above the central portion of the trench 9 in the X direction, a part of the pattern of the gate electrode 2 extending in the Y direction remains in the trench 9 at the central portion in the etching step described with reference to FIG. 23. Since the pattern is formed near the side surface 9b in the trench 9, the gate electrode 2 not covered with the guard region 8 is present in the trench 9. As a result, in order to form the pattern across the central portion of the trench 9 while preventing the electric field from being easily concentrated and the reliability of the gate insulating film from being lowered, it is necessary to form the gate electrode 2 in two formation steps as in the first embodiment.

On the other hand, in the present embodiment, the gate electrode 2 is not formed so as to straddle the central portion of the trench 9 in the X direction. That is, the gate electrode 2 extending in the Y direction and connected to the plurality of trench gate electrodes is formed immediately above the end of the trench 9 in the X direction. That is, the gate electrode 2 extending in the Y direction is formed at a position overlapping the guard region 8 in planar view. In other words, all the regions where the gate electrode 2 extending in the Y direction and the trench 9 overlap in plan view overlap with the guard region 8. Therefore, even if the gate electrode 2 is formed on the side surface 9b side in the trench 9, the electric field concentration at the corner of the trench 9 can be prevented.

Therefore, it is not necessary to form the gate electrodes 2 in the plurality of trenches 9 and the gate electrodes 2 connecting the gate electrodes 2 in parallel on the semiconductor substrate in a separate process. Therefore, the method for manufacturing the silicon carbide semiconductor device can be simplified, and the manufacturing cost can be reduced.

### Third Embodiment

On the upper surface of the semiconductor substrate, for example, a potential fixing region may be formed in order to supply a potential to the body layer 5 and the guard region 8.

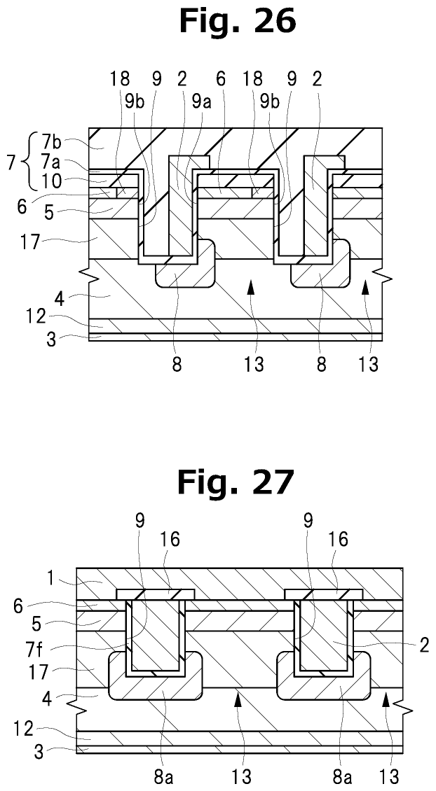

FIG. 25 is a plan view of the silicon carbide semiconductor device according to the present embodiment, and FIG. 26 is a cross-sectional view of the silicon carbide semiconductor device according to the present embodiment. In FIG. 25, a potential fixing region 18 is hatched for easy understanding of the drawing. The potential fixing region 18 corresponds to an eighth semiconductor region.

As illustrated in FIGS. 25 and 26, the source electrode 1 is electrically connected to the potential fixing region 18 that is a p⁺⁺ type semiconductor region formed on the upper surface of the semiconductor substrate. In the Y direction, the source electrode 1 and the potential fixing region 18 are in contact with each other, and the potential fixing region 18 and the trench 9 are in contact with each other on the side surface 9b.

The lower surface of the potential fixing region 18 is in contact with the body layer 5. The potential fixing region 18 has a p type impurity concentration higher than both the body layer 5 and the guard region 8. Since the body layer 5 is electrically connected to the source electrode 1 via the potential fixing region 18, a source voltage can be applied from the source electrode 1 to the body layer 5. In a region not illustrated, the guard region 8 is electrically connected to the source electrode 1 via the potential fixing region 18, so that the source voltage can be applied from the source electrode 1 to the guard region 8.

As described above, the invention made by the inventors has been specifically described based on the embodiments. However, the invention is not limited to the embodiments, and various modifications can be made without departing from the spirit of the invention.

For example, the material, conductivity type, manufacturing conditions, and the like of each part are not limited to the description of the above-described embodiment, and it goes without saying that each part can be modified in many ways. Here, for convenience of description, the conductivity types of the semiconductor substrate and the semiconductor film have been fixed, but the present invention is not limited to the conductivity types described in the above-described embodiment. That is, although the n type SiC power MISFET has been described in the first to third embodiments, the effect of the first to third embodiments can also be obtained in a p type SiC power MISFET in which the conductivity type of each semiconductor region is inverted.

The third embodiment can be combined with either the first embodiment or the second embodiment.

### INDUSTRIAL APPLICABILITY

The present invention can be widely used particularly for a silicon carbide semiconductor device having a trench structure, which is a power semiconductor device.

### REFERENCE SIGNS LIST

2 gate electrode
3 drain electrode
4 drift layer
5 body layer
6 source region
8 guard region
7, 7a to 7e insulating film
9 trench
9a, 9b side surface
12 drain region
13 JFET region
17 current diffusion region
18 potential fixing region

1. A silicon carbide semiconductor device comprising:
a silicon carbide substrate of a first conductivity type;
a semiconductor layer formed on the silicon carbide substrate and containing silicon carbide;
a first semiconductor region of the first conductivity type formed on an upper portion in the semiconductor layer;
a second semiconductor region of a second conductivity type different from the first conductivity type, the second semiconductor region being formed in the semiconductor layer from a lower end of the first semiconductor region to an intermediate depth of the semiconductor layer;
a third semiconductor region of the first conductivity type formed in the semiconductor layer under the second semiconductor region;
a trench formed from the upper surface of the semiconductor layer to an intermediate depth of the third semiconductor region, the trench including a first side surface and a second side surface facing each other in a first direction along the upper surface of the semiconductor layer;
a gate electrode formed inside the trench via an insulating film;
a fourth semiconductor region of the first conductivity type formed in the silicon carbide substrate;
a fifth semiconductor region of the second conductivity type formed in the third semiconductor region below the second semiconductor region; and
a sixth semiconductor region of the first conductivity type formed between the second semiconductor region and the third semiconductor region in the semiconductor layer, wherein
the first semiconductor region, the gate electrode, the second semiconductor region, and the fourth semiconductor region constitute a field effect transistor,
the first side surface is in contact with the second semiconductor region, and a plurality of the trenches and a plurality of the fifth semiconductor regions in contact with the trenches are formed side by side in the first direction,
the first side surface and the second side surface are alternately arranged in the first direction,
the insulating film includes a first insulating film covering the first side surface, a second insulating film covering the second side surface, and a third insulating film covering a bottom surface of the trench,
a film thickness of the second insulating film is larger than a film thickness of the first insulating film in the first direction,
the fifth semiconductor region is in contact with a first surface extending over the first side surface of the trench and a part of the bottom surface, and is separated from a second surface extending over the second side surface of the trench and another part of the bottom surface,
an impurity concentration of the sixth semiconductor region is higher than an impurity concentration of the third semiconductor region and lower than an impurity concentration of the first semiconductor region,
the sixth semiconductor region is in contact with the first side surface and the second side surface of the trench and is separated from a third side surface of the trench in a second direction intersecting the first direction in plan view, and
the fifth semiconductor region covers all corners of four corners of the bottom surface of the trench.

2. The silicon carbide semiconductor device according to claim 1, further comprising:
a source electrode formed on the semiconductor layer and connected to the first semiconductor region; and
a seventh semiconductor region of the first conductivity type formed between the fifth semiconductor regions adjacent to each other in the first direction, wherein
each of the fifth semiconductor region and the seventh semiconductor region extends in the second direction, and
a plurality of the source electrodes extend in the first direction and is arranged side by side in the second direction.

3. The silicon carbide semiconductor device according to claim 1, wherein
the gate electrode has a first portion extending in the second direction on the semiconductor layer and a second portion formed inside each of the plurality of trenches, and
the plurality of second portions of the gate electrode are connected in parallel by the first portion of the gate electrode.

4. The silicon carbide semiconductor device according to claim 3, wherein the first portion of the gate electrode is connected to each of the plurality of second portions of the gate electrode immediately above an end of the trench in the second direction.

5. The silicon carbide semiconductor device according to claim 1, wherein in the second direction, a shortest distance from the third side surface to a terminal end of the fifth semiconductor region in contact with the trench is equal to or longer than a distance between the third side surface and the gate electrode.

6. The silicon carbide semiconductor device according to claim 1, further comprising an eighth semiconductor region of the second conductivity type formed in contact with the second side surface in an upper portion in the semiconductor layer, wherein
the eighth semiconductor region is electrically connected to the second semiconductor region.

7. A method of manufacturing a silicon carbide semiconductor device, the method comprising:
(a) preparing a semiconductor substrate including a silicon carbide substrate of a first conductivity type and a semiconductor layer of the first conductivity type formed on the silicon carbide substrate, containing silicon carbide, and having a third semiconductor region of the first conductivity type therein;
(b) forming a first semiconductor region of the first conductivity type on an upper surface of the semiconductor layer, forming a second semiconductor region of a second conductivity type different from the first conductivity type in the semiconductor layer from a lower end of the first semiconductor region to an intermediate depth of the semiconductor layer, forming a sixth semiconductor region of the first conductivity type in the semiconductor layer from the lower end of the second semiconductor region to the intermediate depth of the semiconductor layer, and forming a plurality of fifth semiconductor regions of the second conductivity type in the third semiconductor region below the second semiconductor region;
(c) forming a plurality of trenches including a first side surface and a second side surface facing each other in a first direction along the upper surface of the semiconductor layer from the upper surface of the semiconductor layer to an intermediate depth of the third semiconductor region;
(d) forming a first insulating film covering a side surface and a bottom surface of the trench;
(e) forming a conductive film inside the trench and on the upper surface of the semiconductor layer via the first insulating film;
(f) forming a gate electrode made of the conductive film by removing a portion of the conductive film facing the second side surface; and
(g) embedding a second insulating film in a region in the trench from which the conductive film has been removed in (f), wherein
the silicon carbide substrate includes a fourth semiconductor region of the first conductivity type inside,
the first semiconductor region, the gate electrode, the second semiconductor region, and the fourth semiconductor region constitute a field effect transistor,
the first side surface is in contact with the second semiconductor region, and a plurality of the trenches and a plurality of the fifth semiconductor regions in contact with the trenches are formed side by side in the first direction,
the first side surface and the second side surface are alternately arranged in the first direction,
the fifth semiconductor region is in contact with a first surface extending over the first side surface of the trench and a part of the bottom surface, and is separated from a second surface extending over the second side surface of the trench and another part of the bottom surface,
an impurity concentration of the sixth semiconductor region is higher than an impurity concentration of the third semiconductor region and lower than an impurity concentration of the first semiconductor region,
the sixth semiconductor region is in contact with the first side surface and the second side surface of the trench and is separated from a third side surface of the trench in a second direction intersecting the first direction in plan view,
the gate electrode has a first portion extending in the second direction and a second portion formed inside each of the plurality of trenches on the semiconductor layer,
the plurality of second portions of the gate electrode are connected in parallel by the first portion of the gate electrode, and
the first portion of the gate electrode is connected to each of the plurality of second portions of the gate electrode immediately above an end of the trench in the second direction.
